(19) United States
(12) Patent Application Publication
(10) Pub. No.: US 2026/0334011 A1
(43) Pub. Date: Oct. 22, 2026

(54) DISPLAY DEVICE AND ELECTRONIC DEVICE

(71) Applicant: Samsung Display Co., LTD., Yongin-si (KR)

(72) Inventors: Gi Na YOO, Yongin-si (KR); Hyo Min KIM, Yongin-si (KR)

(21) Appl. No.: 19/413,288

(22) Filed: Dec. 9, 2025

(30) Foreign Application Priority Data
Apr. 16, 2025 (KR) 10-2025-0049373

(51) Int. Cl. H10K 59/122; G02F 1/13; G02F 1/1333; G02F 1/1335; G02F 1/13357; H10K 59/35; H10K 59/40; H10K 59/50

(52) U.S. Cl. CPC H10K 59/122; G02F 1/1323; G02F 1/13338; G02F 1/133603; G02F 1/133612; G02F 1/133621; H10K 59/352; H10K 59/40; H10K 59/50

(57) ABSTRACT

A display device includes: a base substrate, a pixel electrode disposed on the base substrate, a pixel-defining layer overlapping the pixel electrode on the base substrate and having a first opening defining a pixel, a light-emitting layer formed on the pixel electrode within the first opening, and a transmission control layer disposed on the pixel-defining layer and the light-emitting layer and having a second opening overlapping the first opening and having an area smaller than the first opening.

This application claims priority to Korean Patent Application Number 10-2025-0049373, filed on Apr. 16, 2025, and all the benefits accruing therefrom under 35 U.S.C.§119, the content of which in its entirety is herein incorporated by reference.

### BACKGROUND

### 1. Field

Embodiments of the disclosure relate to a display device including pixel electrodes and insulating layers and an electronic device including the display device.

### 2. Related Art

In display devices such as organic light-emitting diode (OLED) display devices and liquid crystal display devices (LCD), a display substrate including thin film transistors (TFT) and various wiring is provided. A display structure including electrodes and emissive layers is formed on the display substrate.

A pixel area includes red pixel area, green pixel area, and blue pixel area, and optical characteristics of each pixel area may affect display quality.

Recently, display devices that can adjust visibility in the display area have been developed in response to the desire to prevent personal information exposure.

### SUMMARY

The disclosure provides a display device and an electronic device including the display device which may improve optical characteristics and display characteristics.

A display device according to some embodiments of the present disclosure includes: a base substrate, a pixel electrode disposed on the base substrate, a pixel-defining layer overlapping the pixel electrode on the base substrate and having a first opening defining a pixel, a light-emitting layer formed on the pixel electrode within the first opening, and a transmission control layer disposed on the pixel-defining layer and the light-emitting layer and having a second opening overlapping the first opening and having an area smaller than the first opening.

According to some embodiments, the transmission control layer may include a first electrode, a second electrode, and a transmission conversion layer disposed between the first electrode and the second electrode.

According to some embodiments, the transmission conversion layer may include a liquid crystal material or a dichroic dye material.

According to some embodiments, the display device may further include a touch-sensing electrode layer disposed on the pixel-defining layer. The first electrode or the second electrode may be positioned at a same level as the touch-sensing electrode layer.

According to some embodiments, the touch-sensing electrode layer may include a first touch-sensing electrode layer and a second touch-sensing electrode layer. The transmission conversion layer may be provided as an insulating layer between the first touch-sensing electrode layer and the second touch-sensing electrode layer.

According to some embodiments, the display device may operate according to a private mode in which no power is applied to the first electrode and the second electrode by the display device, and the display device may operate according to a normal mode in which power is applied to the first electrode and the second electrode by the display device.

According to some embodiments, in the normal mode, a first emission area corresponding to the first opening may be driven, and in the private mode, a second emission area corresponding to the second opening and having a reduced area from the first emission area may be driven.

According to some embodiments, the pixel may include a first pixel, a second pixel, and a third pixel of different colors. An area of the second emission area included in the second pixel may be smaller than an area of the second emission area included in each of the first pixel and the third pixel.

According to some embodiments, the second pixel may correspond to a green pixel.

According to some embodiments, the pixel may include a first pixel, a second pixel, and a third pixel of different colors. The transmission conversion layer may include a first transmission conversion layer overlapping the first pixel, a second transmission conversion layer overlapping the second pixel, and a third transmission conversion layer overlapping the third pixel. The first transmission conversion layer, the second transmission conversion layer, and the third transmission conversion layer may respectively include dichroic dye materials of different respective colors.

According to some embodiments, the second opening may be included in the first opening in a plan view.

A display device according to some embodiments of the present disclosure includes: a base substrate, a pixel electrode disposed on the base substrate, a pixel-defining layer overlapping the pixel electrode on the base substrate and defining a first emission area associated with operation of a pixel according to a normal mode, a light-emitting layer formed on the pixel electrode and corresponding to the first emission area, and a transmission control layer disposed on the pixel-defining layer and the light-emitting layer, included in the first emission area, and defining a second emission area associated with operation of the pixel according to a private mode.

According to some embodiments, the transmission control layer may include a first electrode, a second electrode, and a transmission conversion layer disposed between the first electrode and the second electrode and including a liquid crystal material or a dichroic dye material.

According to some embodiments, in the normal mode, the liquid crystal material or the dichroic dye material may be vertically oriented.

According to some embodiments, in the private mode, the liquid crystal material or the dichroic dye material may be randomly oriented.

According to some embodiments, the pixel may include a first pixel, a second pixel, and a third pixel of different respective colors. The pixel-defining layer may define respective first emission areas associated with operation of the first pixel, the second pixel, and the third pixel according to the normal mode. The transmission control layer may define respective second emission areas associated with operation of the first pixel, the second pixel, and the third pixel according to the private mode. A second gap, which is a separation distance between respective boundaries of the first emission area and the second emission area associated with the second pixel, may be larger than a first gap, which is a separation distance between respective boundaries of the first emission area and the second emission area associated with the first pixel. The second gap may be larger than a third gap, which is a separation distance between respective boundaries of the first emission area and the second emission area associated with the third pixel.

According to some embodiments, the second pixel may correspond to a green pixel.

According to some embodiments, the pixel-defining layer may include a first opening corresponding to the first emission area, and the transmission control layer may include a second opening corresponding to the second emission area and having a smaller area than the first opening.

An electronic device according to some embodiments of the present disclosure includes: a display device, a memory, and a processor configured to execute data included in the memory to control operation of the display device. The display device may include a base substrate, a pixel electrode disposed on the base substrate, a pixel-defining layer overlapping the pixel electrode on the base substrate and having a first opening defining a pixel, a light-emitting layer formed on the pixel electrode within the first opening, and a transmission control layer disposed on the pixel-defining layer and the light-emitting layer and having a second opening overlapping the first opening and having an area smaller than the first opening.

According to some embodiments, the electronic device may include virtual reality or augmented reality glasses, a smartphone, a tablet PC, a laptop, a television, a desk monitor, a smart glass, a head-mounted display, a smart watch, or an automotive display.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a schematic plan view of a display device in accordance with an embodiment.

FIG. 2 is an equivalent circuit diagram of a pixel of a display device in accordance with an embodiment.

FIG. 3 is a schematic plan view of a display device in accordance with an embodiment.

FIG. 4 is a schematic cross-sectional view of a display device in accordance with an embodiment.

FIG. 5 is a schematic cross-sectional view illustrating emission characteristics in a private mode of a display device in accordance with embodiments.

FIG. 6 is a schematic cross-sectional view illustrating emission characteristics in a normal mode of a display device in accordance with embodiments.

FIG. 7 is a schematic cross-sectional view of a display device in accordance with embodiments.

FIG. 8 is a schematic plan view of a display device in accordance with embodiments.

FIG. 9 is a schematic cross-sectional view of a display device in accordance with embodiments.

FIG. 10 is a schematic plan view of a display device in accordance with embodiments.

FIG. 11 is an exploded perspective view of an electronic device in accordance with embodiments.

FIG. 12 is a schematic block diagram of an electronic device in accordance with embodiments.

FIG. 13 is schematic diagrams of an electronic device in accordance with embodiments.

### DETAILED DESCRIPTION

The disclosure now will be described more fully hereinafter with reference to the accompanying drawings, in which various embodiments are illustrated. This disclosure may, however, be embodied in many different forms, and should not be construed as limited to the embodiments set forth herein. Rather, the example embodiments are provided such that this disclosure will be thorough and complete, and will fully convey the scope of the disclosure to those skilled in the art.

In describing the drawings, like reference numerals have been used for like elements. In the accompanying drawings, the dimensions of the structures are enlarged than the actual size in order to clearly explain the disclosure. It will be understood that, although the terms "first", "second", and the like may be used herein to describe various elements, these elements should not be limited by these terms. These terms are used to distinguish one element from another element. For instance, a first element discussed below could be termed a second element without departing from the scope of the disclosure. Similarly, the second element could also be termed the first element.

The terminology used herein is for the purpose of describing particular embodiments and is not intended to be limiting. As used herein, "a", "an", "the", and “at least one” do not denote a limitation of quantity, and are intended to include both the singular and plural, unless the context clearly indicates otherwise. For example, "an element" has the same meaning as “at least one element", unless the context clearly indicates otherwise. “At least one” is not to be construed as limiting “a” or “an”. “Or” means “and/or”. As used herein, the term “and/or” includes any and all combinations of one or more of the associated listed items. It will be further understood that the terms “comprises” and/or “comprising”, or “includes” and/or “including” when used in this specification, specify the presence of stated features, areas, integers, steps, operations, elements, and/or components, but do not preclude the presence or addition of one or more other features, areas, integers, steps, operations, elements, components, and/or groups thereof.

In the following description, when a first part is "connected" to a second part, this includes not only the case where the first part is directly connected to the second part, but also the case where a third part is interposed therebetween and they are connected to each other.

Furthermore, relative terms, such as “lower” or “bottom” and “upper” or “top” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower” may therefore, encompasses both an orientation of “lower” and “upper” depending on the particular orientation of the figure. Similarly, when the device in one of the drawing figures is turned over, elements described as “below” or “beneath” other elements would then be oriented “above” the other elements. The terms “below” or “beneath” can, therefore, encompass both an orientation of above and below.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially blocked” means approximately or actually blocked.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, embodiments of the disclosure will be described in detail with reference to the accompanying drawings.

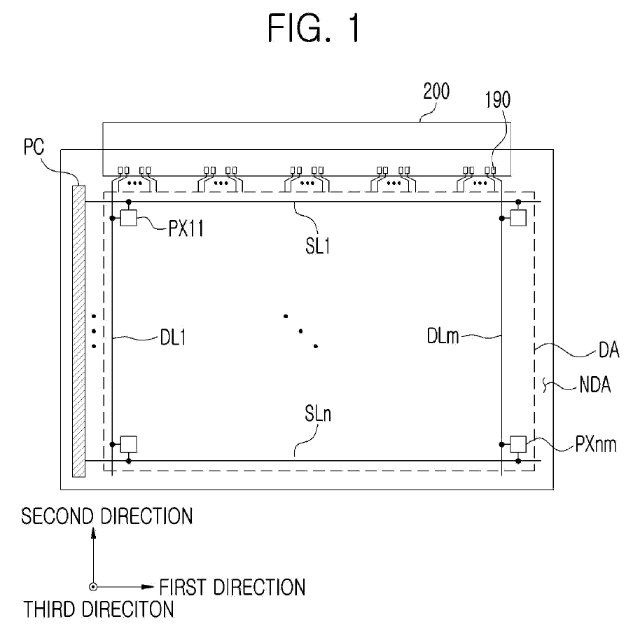

FIG. 1 is a schematic plan view of a display device in accordance with an embodiment.

In FIG. 1, a first direction and a second direction may refer to two directions parallel to a display surface of a display device and perpendicular to each other. For example, the first direction may correspond to X direction (or row direction) of the display device and the second direction may correspond to Y direction (or column direction) of the display device. A third direction may be perpendicular to the first direction and the second direction. The third direction may correspond to the Z direction (or thickness direction) of the display device.

The above definitions of direction may be applied equally to the following drawings.

Referring to FIG. 1, a plurality of pixels PX11 to PXnm may be arranged in a display area DA of the display device.

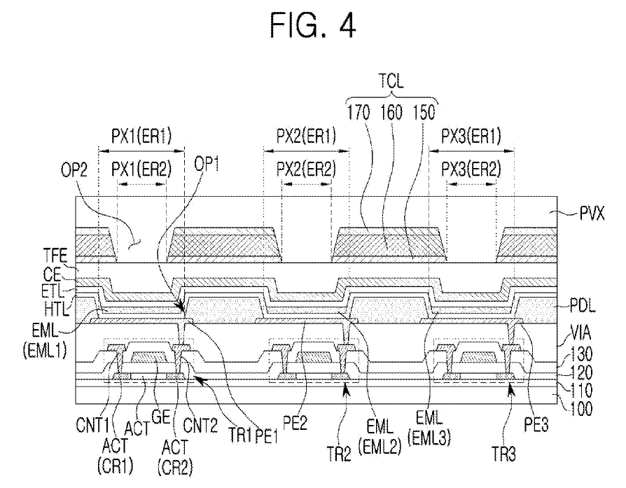

A pixel circuit including scan lines SL1 to SLn (or gate lines) forming a first row to an n row and data lines DL1 to DLm forming a first column to an m column may be arranged on a base substrate 100 (refer to FIG. 4) of the display device. Each of the pixels PX11 to PXnm may be connected to a corresponding scan line of n row among the scan lines SL1 to SLn and a corresponding data line of m column among the data lines DL1 to DLm.

Each of the pixels PX11 to PXnm may further include a pixel circuit including transistors and a light-emitting element, as described later. Although not illustrated in detail in FIG. 1, the pixel circuit may further include wirings such as power lines, ground lines, and the like.

In FIG. 1, the data lines DL1 to DLm are illustrated extending in the second direction and the scan lines SL1 to SLn are illustrated extending in the first direction, but the embodiments are not necessarily limited to the aforementioned example.

A peripheral circuit PC may be disposed in the non-display area NDA corresponding to a peripheral area with respect to the display area DA. For example, the peripheral circuit PC may include a gate driver circuit. The gate driver circuit may be integrated into the display device through an oxide semiconductor gate (OSG) driver circuit process, an amorphous silicon gate (ASG) driver circuit process, or a polysilicon gate (PSG) driver circuit process.

The peripheral circuit PC may further include a data driver, a gate driver, an emission driver, a power voltage generator, a timing controller, and the like.

The display device may further include a printed circuit board 200. Pads 190 of the pixel circuit may be aggregated on one side of the non-display area NDA. The printed circuit board 200 may be electrically connected to the pixel circuit through the pads 190. For example, the printed circuit board 200 may be electrically connected to the pads 190 through a heat-press process utilizing a conductive interposition structure, such as an anisotropic conductive film (ACF).

An integrated circuit (IC), such as a data driver circuit, may be disposed on the printed circuit board 200. For example, an integrated circuit (IC) chip may be mounted on the printed circuit board 200 in a form of a chip-on-film (COF).

In the following, configurations/structures of the disclosed display device may be described using an organic light-emitting display as an example. However, the display device disclosed herein may also be applied to various other types of display devices, such as inorganic light-emitting display device, quantum dot light-emitting display device, and the like.

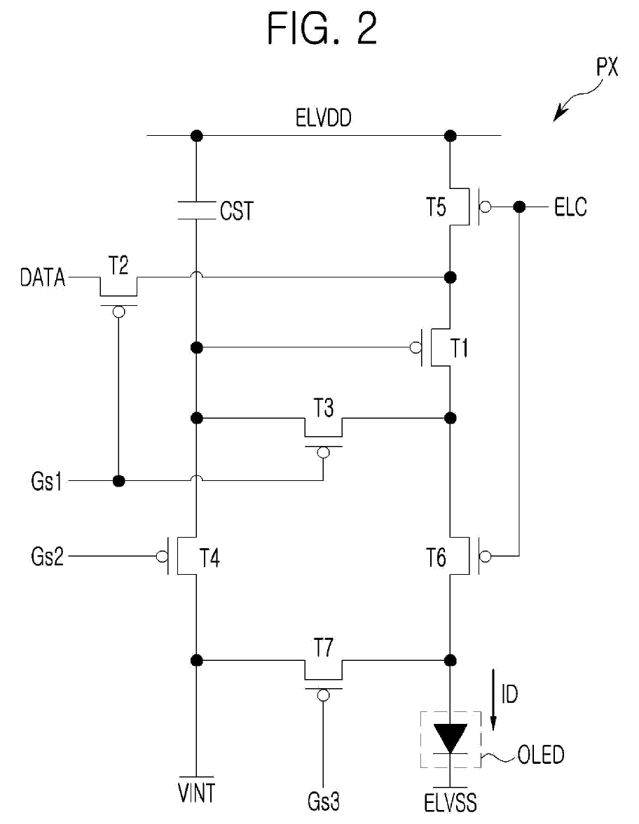

FIG. 2 is an equivalent circuit diagram of a pixel of a display device in accordance with an embodiment.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal, and a second terminal. The gate terminal of the first transistor T1 may be connected to the storage capacitor CST. The first terminal of the first transistor T1 may be connected to the second transistor T2. The second terminal of the first transistor T1 may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may be provided with a first gate signal Gs1. The second transistor T2 may be turned on or turned off in response to the first gate signal Gs1. The first terminal of the second transistor T2 may be provided with a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal, and a second terminal. The gate terminal of the third transistor T3 may be provided with the first gate signal Gs1. The first terminal of the third transistor T3 may be connected to the gate terminal of the first transistor T1. The second terminal of the third transistor T3 may be connected to the second terminal of the first transistor T1. The third transistor T3 may compensate a threshold voltage of the first transistor T1. For example, the third transistor T3 may be referred to as a compensation transistor.

The fourth transistor T4 may include a gate terminal, a first terminal, and a second terminal. The gate terminal of the fourth transistor T4 may be provided with a second gate signal Gs2. The first terminal of the fourth transistor T4 may be connected to the gate terminal of the first transistor T1. The second terminal of the fourth transistor T4 may be provided with an initialization voltage VINT. The fourth transistor T4 may initialize the gate terminal of the first transistor T1.

The fifth transistor T5 may include a gate terminal, a first terminal, and a second terminal. The gate terminal of the fifth transistor T5 may be provided with an emission control signal ELC. The first terminal of the fifth transistor T5 may be provided with a high power voltage ELVDD. The second terminal of the fifth transistor T5 may be connected to the first transistor T1.

The sixth transistor T6 may include a gate terminal, a first terminal, and a second terminal. The gate terminal of the sixth transistor T6 may be provided with the emission control signal ELC. The first terminal may be connected to the first transistor T1. The second terminal of the sixth transistor T6 may be connected to an organic light-emitting diode OLED. The sixth transistor T6 may deliver the driving current ID to the organic light-emitting diode OLED in response to the emission control signal ELC.

The seventh transistor T7 may include a gate terminal, a first terminal, and a second terminal. The gate terminal of the seventh transistor T7 may be provided with a third gate signal Gs3. The first terminal seventh transistor T7 may be connected to the organic light-emitting diode OLED. The second terminal seventh transistor T7 may be provided with the initialization voltage VINT. The seventh transistor T7 may initialize the organic light-emitting diode OLED. The storage capacitor CST may include a first terminal and a second terminal. The first terminal of the storage capacitor CST may be provided with the high power voltage ELVDD. The second terminal of the storage capacitor CST may be connected to the gate terminal of the first transistor T1.

The organic light-emitting diode OLED may include a first terminal and a second terminal. The first terminal of the organic light-emitting diode OLED may be connected to the sixth transistor T6. The second terminal of the organic light-emitting diode OLED may be provided with a low power voltage ELVSS. The organic light-emitting diode OLED may emit lights based on the driving current ID.

In FIG. 2, a structure of a 7T1C with seven thin-film transistors and one storage capacitor CST per the pixel PX is illustrated, but the embodiments are not necessarily limited to the aforementioned example.

For example, each pixel PX may include two or more transistors, and may have a structure of 2T1C, 3T2C, 5T2C, 6T2C, and the like.

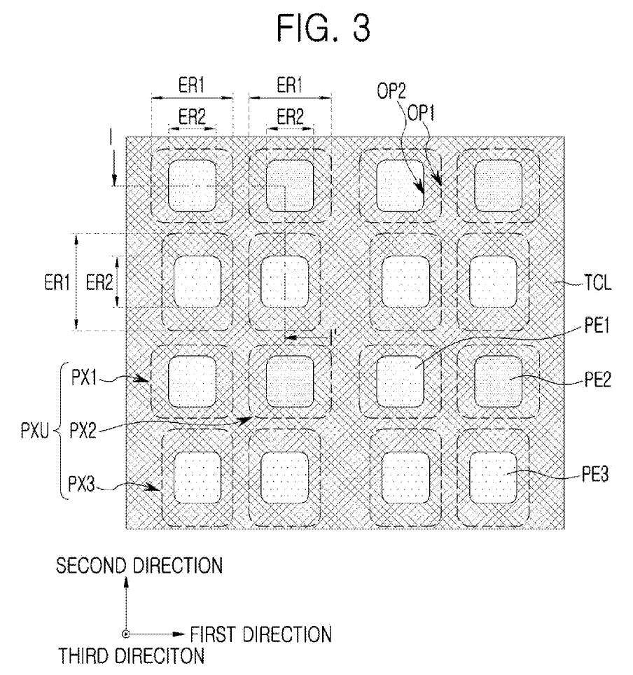

FIG. 3 is a schematic plan view of a display device in accordance with an embodiment. FIG. 4 is a schematic cross-sectional view of a display device in accordance with an embodiment.

FIG. 3 is a schematic plan view illustrating a pixel arrangement of the display device. FIG. 4 is a schematic cross-sectional view taken along the line I-I' of FIG. 1 in the third direction (or thickness direction).

Referring to FIG. 3, the display device may include a first pixel PX1, a second pixel PX2, and a third pixel PX3 respectively corresponding to emission areas of different respective colors. According to example embodiments, the first pixel PX1, the second pixel PX2, and the third pixel PX3 may correspond to a red pixel (R), a green pixel (G), and a blue pixel (B), respectively.

Each pixel may refer to an emission area defined by a pixel-defining layer PDL. For example, a first pixel PX1 may refer to an area of a first opening OP1 that exposes a pixel electrode of the pixel-defining layer PDL.

According to example embodiments, the first pixel PX1 and the second pixel PX2 may be alternately and repeatedly arranged along the first direction. The third pixel PX3 may be arranged between the neighboring first pixels PX1 and the neighboring second pixels PX2 in the second direction.

For example, a pixel unit PXU may be defined by a pair of the first pixel PX1 and the second pixel PX2 neighboring in the first direction and the third pixels PX3 adjacent to the pair of first pixel PX1 and second pixel PX2. As illustrated in FIG. 3, the pixel unit PXU may include one first pixel PX1, one second pixel PX2, and two third pixels PX3.

The pixel unit PXU may include a plurality of third pixels PX3 corresponding to blue pixels having relatively low life-time stability or degradation stability, thereby improving an overall emission stability of the display device.

The pixel units PXU may be arranged repeatedly along the first direction and the second direction.

Referring to FIG. 4, the display device may include first to third transistor structures TR1, TR2, and TR3 formed on the base substrate 100, first to third pixel electrodes PE1, PE2, and PE3 electrically connected to the first to third transistor structures TR1, TR2, and TR3 through via electrodes, respectively, and first to third light-emitting layers EML1, EML2, and EML3 formed on the first to third pixel electrodes PE1, PE2, and PE3, respectively.

The base substrate 100 may be provided as a support substrate or a back-plane substrate of the display device. A glass substrate or a plastic substrate may be used as the base substrate 100.

In some embodiments, the base substrate 100 may include a polymeric material that is transparent and flexible. In this case, the base substrate 100 may be employed in a transparent flexible display device. For example, the base substrate 100 may include a polymeric material such as a polyimide, a polysiloxane, an epoxy-based resin, an acrylic-based resin, or a polyester. In an embodiment, the base substrate 100 may include a polyimide.

A buffer layer 110 may be formed on a top surface of the base substrate 100. The buffer layer 110 may block moisture from infiltrating through the base substrate 100, and a diffusion of impurities between the base substrate 100 and the structures formed on the base substrate 100 may be blocked.

The buffer layer 110 may be formed entirely across the display area DA and the non-display area NDA of the base substrate 100, and the buffer layer 110 may cover the top surface of the base substrate 100 entirely.

The buffer layer 110 may include an inorganic insulating material, such as a silicon oxide, a silicon nitride, or a silicon oxynitride. These may be used alone or in combination with two or more . In some embodiments, the buffer layer 110 may have a laminated structure including a silicon oxide film and a silicon nitride film. The buffer layer 110 may be formed through a deposition process, such as a chemical vapor deposition (CVD) process, a sputtering process, an atomic layer deposition (ALD) process, or the like, to include the inorganic insulating material described herein.

The first to third transistor structures TR1, TR2, and TR3 may be disposed on the buffer layer 110. The first transistor structure TR1, the second transistor structure TR2, and the third transistor structure TR3 may be electrically connected to the first pixel electrode PE1, the second pixel electrode PE2, and the third pixel electrode PE3, respectively.

The first to third transistor structures TR1, TR2, and TR3 may each include an active layer ACT, a gate insulating layer 120, and a gate electrode GE. The first to third transistor structures TR1, TR2, and TR3 may each further include contact electrodes CNT1, CNT2 connected to the active layer ACT.

The active layer ACT may be disposed on the buffer layer 110 and may be patterned, for example, through a photo etch process. Based on the patterning, the active layer ACT may have a repetitive/regular arrangement for each pixel area. The active layer ACT may include a silicon compound, such as an amorphous silicon or a polysilicon. Some regions of the active layer ACT may be doped with p-type dopants or n-type dopants, and may include a source region, a drain region, and a channel region.

The active layer ACT may include an oxide semiconductor such as an indium gallium zinc oxide (IGZO), a zinc tin oxide (ZTO), or an indium tin zinc oxide (ITZO).

The gate insulating layer 120 may be formed on the active layer ACT, and the gate electrode GE may be stacked on the gate insulating layer 120. As illustrated in FIG. 4, the gate insulating layer 120 may extend continuously across a plurality of pixels and may be common to the first to third transistor structures TR1, TR2, and TR3.

In contrast, the gate insulating layer 120 may partially cover each active layer ACT and may be formed in an independent pattern on each of the first to third transistor structures TR1, TR2, and TR3.

The gate electrode GE may overlap the channel region of the active layer ACT in the third direction. Scan signals from the scan lines SL1 to SLn (refer to FIG. 1) may be transmitted through the gate electrode GE.

The gate insulating layer 120 may be formed through the deposition process described herein to include an inorganic insulating material such as a silicon oxide, a silicon nitride, a silicon oxynitride, a metal oxide, or the like.

In some embodiments, p-type dopants or n-type dopants may be implanted into the active layer ACT through an ion implantation process using the gate electrode GE as an ion implantation mask. Accordingly, a first contact region CR1 and a second contact region CR2 may be formed on one side and the other side of the active layer ACT, respectively. The first contact region CR1 and the second contact region CR2 may correspond to the source region and the drain region, respectively.

A portion of the active layer ACT between the first contact region CR1 and the second contact region CR2 and overlapping the gate electrode GE in the third direction (or thickness direction) may be defined as the channel region.

In some embodiments, the gate insulating layer 120 may be formed in a pattern covering the channel region by an etch process using the gate electrode GE as an etch mask. when the active layer ACT includes an oxide semiconductor, a hydrogen (H) included in an interlayer insulating layer 130 may diffuse or migrate into the active layer ACT upon formation of the interlayer insulating layer 130. Accordingly, a carrier concentration may be increased by the hydrogen (H), and the contact regions CR1, CR2 may be formed on side portions of the active layer ACT.

The interlayer insulating layer 130 covering the gate insulating layer 120 and the gate electrode GE may be formed on the active layer ACT. The interlayer insulating layer 130 may be formed through the deposition process described herein to include an inorganic insulating material such as a silicon oxide, a silicon nitride, a silicon oxynitride, or the like. The interlayer insulating layer 130 may be formed as a single-layered structure or a multi-layered structure including different materials.

The contact electrodes CNT1, CNT2 that are in contact or electrically connected to the active layer ACT may be formed on the interlayer insulating layer 130.

The contact electrodes CNT1, CNT2 may include a first contact electrode CNT1 in contact or electrically connected to the first contact region CR1 of the active layer ACT and a second contact electrode CNT2 in contact or electrically connected to the second contact region CR2 of the active layer ACT. The first contact electrode CNT1 and the second contact electrode CNT2 may be provided as a source electrode and a drain electrode, respectively.

According to example embodiments, the interlayer insulating layer 130 may be partially etched to form contact holes. For example, the contact holes may expose the first contact region CR1 and the second contact region CR2, respectively. After forming a metal layer sufficiently filling the contact holes on the interlayer insulating layer 130, the metal layer may be partially etched to form the first contact electrode CNT1 and the second contact electrode CNT2. For example, data signals from the data lines DL1 to DLm (refer to FIG. 1) may be transmitted through the first contact electrode CNT1.

The gate electrode GE and the contact electrodes CNT1, CNT2 may include a metal such as Ag, Mg, Al, W, Cu, Ni, Cr, Mo, Ti, Pt, Ta, Nd, Sc, and others, alloys thereof, or nitrides thereof. The gate electrode GE and the contact electrodes CNT1, CNT2 may be formed by a deposition process, such as a sputtering process.

The gate electrode GE and the contact electrodes CNT1, CNT2 may be formed in a multi-layered structure (e.g., Ti layer, Al layer, and Ti layer).

A via insulating layer VIA covering the contact electrodes CNT1 and CNT2 may be formed on the interlayer insulating layer 130. The via insulating layer may be provided substantially as a planarization layer of a thin-film transistor (TFT) array.

The via insulating layer VIA may include via electrodes electrically connecting the first to third pixel electrodes PE1, PE2, and PE3 and the second contact electrodes CNT2, respectively.

In some embodiments, the via insulating layer VIA may include an organic material such as a polyimide, an epoxy-based resin, an acrylic-based resin, a polyester, a siloxane-based resin, a benzocyclobutene (BCB), or the like. The via insulating layer VIA may be formed through a coating process, such as the deposition process described herein or a spin coating process.

The first pixel electrode PE1, the second pixel electrode PE2, and the third pixel electrode PE3 may be formed in the first pixel PX1, the second pixel PX2, and the third pixel PX3, respectively. The first pixel electrode PE1, the second pixel electrode PE2, and the third pixel electrode PE3 may be electrically connected to the second contact electrodes CNT2 included in the first transistor structure TR1, the second transistor structure TR2, and the third transistor structure TR3, respectively.

For example, the via insulating layer VIA may be partially etched to form via holes that expose a top surface of the second contact electrodes CNT2. A conductive layer including a metallic material or a transparent conductive oxide sufficiently filling the via holes may be formed on a top surface of the via insulating layer VIA, and then the conductive layer may be etched to form the first to third pixel electrodes PE1, PE2, and PE3.

In some embodiments, one or more via electrodes may be stacked on the second contact electrodes CNT2 within the via insulating layer VIA, and the first to third pixel electrodes PE1, PE2, and PE3 may be electrically connected to the second contact electrodes CNT2 through the via electrodes, respectively.

The first to third pixel electrodes PE1, PE2, and PE3 are provided as anodes and may include a high work function conductive material that promotes hole injection. The first to third pixel electrodes PE1, PE2, and PE3 may be provided as transparent electrodes. The first to third pixel electrodes PE1, PE2, and PE3 may include a transparent conductive oxide such as an indium tin oxide (ITO), an indium zinc oxide (IZO), a zinc oxide (ZnO), an indium tin zinc oxide (ITZO), and the like.

The first to third pixel electrodes PE1, PE2, and PE3 may be provided as semi-transparent electrodes or reflective electrodes. The first to third pixel electrodes PE1, PE2, and PE3 may include a metal selected from Ag, Mg, Cu, Al, Pt, Pd, Au, Ni, Nd, Ir, Cr, Li, Ca, LiF, Mo, Ti, W, In, Sn, Zn, or an alloy of two or more of these.

The first to third pixel electrodes PE1, PE2, and PE3 may have a single-layered structure or a multi-layered structure. For example, The first to third pixel electrodes PE1, PE2, and PE3 may have a three-layered structure of ITO/Ag/ITO, or ITO/Al/ITO.

The pixel-defining layer PDL that exposes upper surfaces of the first to third pixel electrodes PE1, PE2, and PE3 may be formed on the via insulating layer VIA. The pixel-defining layer PDL may be formed to at least partially expose the upper surfaces of the first to third pixel electrodes PE1, PE2, and PE3 and each pixel may be defined. The pixel-defining layer PDL may cover peripheries of the first to third pixel electrodes PE1, PE2, and PE3.

The pixel-defining layer PDL may be formed continuously over substantially an entire area of the display area DA and may include first openings OP1 that overlap upper surfaces of the first to third pixel electrodes PE1, PE2, and PE3, respectively.

Boundary of the first openings OP1 may be defined by lines where sides of the pixel-defining layer PDL and the upper surfaces of the first to third pixel electrodes PE1, PE2, and PE3 meet. First emission areas ER1 may be defined by the first openings OP1. The first emission areas ER1 may be included in the first pixel PX1, the second pixel PX2, and the third pixel PX3, respectively.

Light-emitting layers EML may be disposed on the upper surfaces exposed by the first openings OP1 of the first to third pixel electrodes PE1, PE2, and PE3, respectively. In some embodiments, the light-emitting layers EML may include an organic light-emitting material that is independently patterned for each of the red, green, and blue pixels to produce different colored light for each pixel.

For example, the organic light-emitting material may include a host material that is excited by holes and electrons, and a dopant material that increases luminescence efficiency through absorption and release of an energy.

The light-emitting layers EML may include a first light-emitting layer EML1, a second light-emitting layer EML2, and a third light-emitting layer EML3 formed on the first pixel electrode PE1, the second pixel electrode PE2, and the third pixel electrode PE3, respectively. The first light-emitting layer EML1, the second light-emitting layer EML2, and the third light-emitting layer EML3 may correspond to a red light-emitting layer, a green light-emitting layer, and a blue light-emitting layer, respectively.

A hole transport layer HTL may be disposed between the first to third pixel electrodes PE1, PE2, and PE3 and the light-emitting layers EML. In some embodiments, a hole injection layer may be further formed between the hole transport layer HTL and the first to third pixel electrodes PE1, PE2, and PE3.

An electron transport layer ETL may be formed on the light-emitting layers EML. In some embodiments, an electron injection layer may be further formed on the electron transport layer ETL.

The hole transport layer HTL and the electron transport layer ETL may extend in common, continuously across a plurality of emission areas or the first to third pixels PX1, PX2, and PX3.

For example, the hole transport layer HTL may include m-MTDATA (4,4',4"-[tris(3-methylphenyl)phenylamino] triphenylamine), TDATA (4,4'4"-tris(N,N-diphenylamino)triphenylamine), 2-TNATA(4,4',4"-tris[N(2-naphthyl)-N-phenylamino]-triphenylamine), NPB(N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), and the like.

For example, the electron transport layer ETL may include an anthracene-based compound, Alq_{(3) (}tris(8-hydroxyquinolinato)aluminum), TPBi (1,3,5-Tri(1-phenyl-1H-benzo[d]imidazol-2-yl)benzene), BCP(2,9-dimethyl-4,7-diphenyl-1,10-phenanthroline), Bphen(4,7-diphenyl-1,10-phenanthroline), TAZ(3-(4-biphenylyl)-4-phenyl-5-tert-butylphenyl-1,2,4-triazole), NTAZ(4-(naphthalen-1-yl)-3,5-diphenyl-4H-1,2,4- triazole), tBu-PBD(2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), and the like.

The light-emitting layers EML, the hole transport layer HTL, and/or the electron transport layer ETL may be formed through a process such as a thermal deposition, a vapor deposition, a vacuum deposition, a spin coating, an inkjet printing, a laser printing, a casting, a laser thermal transfer, and the like.

An opposing electrode CE may be disposed on the pixel-defining layer PDL and the light-emitting layers EML. In some embodiments, the opposing electrode CE may be formed on the electron transport layer ETL.

The opposing electrode CE may be a common electrode common to the plurality of emission areas or the first to third pixels PX1, PX2, and PX3.

The opposing electrode CE may be provided as an electron injection electrode or cathode. The opposing electrode CE may include a metal, alloy, electrically conductive compound, or the like having a low work function.

For example, the opposing electrode CE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, and the like. These may be used alone or in combination of two or more.

The opposing electrode CE may be provided as a transparent electrode, a semi-transparent electrode, or a reflective electrode. The opposing electrode CE may have a single-layered structure or a multi-layered structure.

Light-emitting elements for pixels may be defined by the stacked structure of the first to third pixel electrodes PE1, PE2, and PE3, the hole transport layer HTL, the light-emitting layers EML, the electron transport layer ETL, and the opposing electrode CE described herein. For example, the light-emitting elements may be electrically connected to the first to third transistor structures TR1, TR2, and TR3 through the second contact electrodes CNT2, respectively.

An encapsulation layer TFE may be formed on the opposing electrode CE. The encapsulation layer TFE may protect the light-emitting layers EML from moisture or oxygen.

The encapsulation layer TFE may be an inorganic film including silicon nitride (SiNx), silicon oxide (SiOx), indium tin oxide, indium zinc oxide, or any combination thereof, an organic film including polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, or the like), epoxy resin (e.g., aliphatic glycidyl ether (AGE), or the like), or any combination thereof, or a combination of inorganic and organic films.

The encapsulation layer TFE may be formed in a single-layered structure or a multi-layered structure. In some embodiments, the encapsulation layer TFE may have a sequential stacking structure of a first inorganic layer, an organic layer, and a second inorganic layer.

According to embodiments of the present disclosure, the display device may include a transmission control layer TCL disposed on the encapsulation layer TFE. The transmission control layer TCL may include a first electrode 150, a transmission conversion layer 160, and a second electrode 170 stacked sequentially on the encapsulation layer TFE.

The first electrode 150 and the second electrode 170 may be provided as transparent electrodes. According to example embodiments, the first electrode 150 and the second electrode 170 may include transparent conductive oxides such as indium tin oxide (ITO), indium zinc oxide (IZO), zinc oxide (ZnO), indium tin zinc oxide (ITZO), and the like.

The transmission conversion layer 160 may include a liquid crystal material and/or a dye material, as described later. The transmission conversion layer 160 may further include a binder resin to disperse the liquid crystal material and/or the dye material. According to example embodiments, the transmission conversion layer 160 may be formed from a polymer dispersed liquid crystal (PDLC) film.

The transmission conversion layer 160 may include second openings OP2 that cover the pixel-defining layer PDL as a whole and overlap the first to third light-emitting layers EML1, EML2, and EML3, respectively or the first to third pixel electrodes PE1, PE2, and PE3, respectively.

In a plan view, the second openings OP2 are included in the first openings OP1, and an area of each of the second openings OP2 may be smaller than an area of each of the first openings OP1. Accordingly, second emission areas ER2 having reduced areas than the first emission areas ER1 may be defined by the second openings OP2.

According to example embodiments, the transmission control layer TCL may shield peripheries of the first openings OP1 or the first emission areas ER1 and cover the pixel-defining layer PDL. For example, portions of the first to third pixel electrodes PE1, PE2, and PE3 or the first to third light-emitting layers EML1, EML2, and EML3 disposed at the peripheries of the first emission areas ER1 may be shielded by the transmission control layer TCL.

For example, a first transparent electrode layer, a coating layer including the liquid crystal material and/or the dye material, and a second transparent electrode layer may be formed sequentially on the encapsulation layer TFE to form a laminate. Then, portions of the laminate corresponding to the second openings OP2 may be etched to form the transmission control layer TCL.

A passivation layer PVX may be formed on the transmission control layer TCL. The passivation layer PVX may include an organic insulating material or an inorganic insulating material as described herein. The passivation layer PVX may fill the second openings OP2 and may cover the transmission control layer TCL.

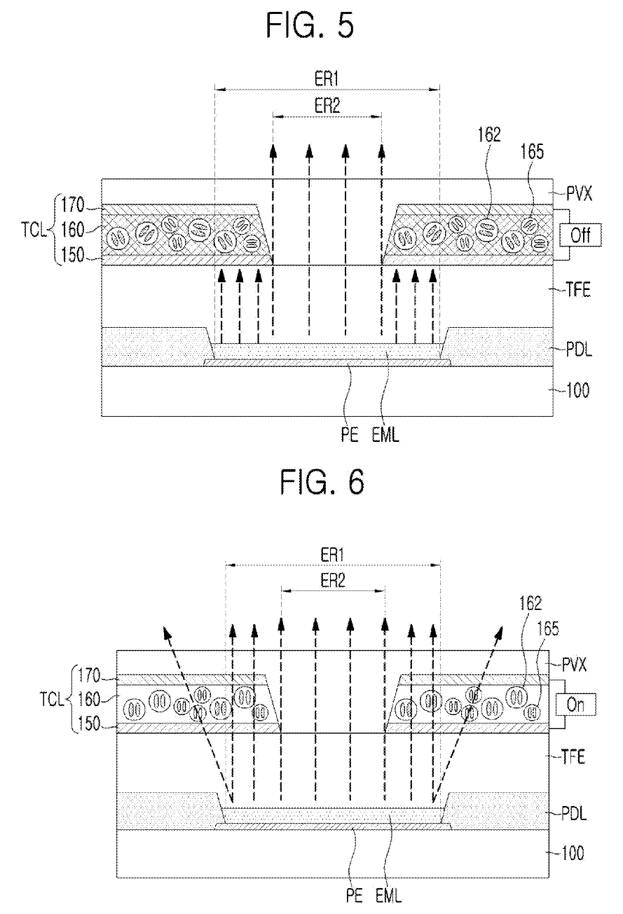

FIG. 5 is a schematic cross-sectional view illustrating emission characteristics in a private mode of a display device in accordance with embodiments.

Referring to FIG. 5, a liquid crystal material 162 and/or a dye material 165 may be dispersed within the transmission conversion layer 160, as described herein.

The liquid crystal material 162 may include a nematic liquid crystal material whose arrangement is changed by a vertical electric field. The dye material 165 may include a dichroic dye. In some embodiments, the dye material 165 may include a black dye. In some embodiments, the dye material 165 may include a red dye, a green dye, and a blue dye together.

According to example embodiments, the transmission conversion layer 160 may include the liquid crystal material 162 and the dye material 165 together.

In the off state, where no power is applied to the first electrode 150 and the second electrode 170 (e.g., when the display device applies no power to the first electrode 150 and the second electrode 170), the liquid crystal material 162 and the dye material 165 may have a randomized orientation. Accordingly, light may be scattered by the liquid crystal material 162 and blocked or absorbed by the dye material 165 and thereby implement a private mode (e.g., a light-blocking mode).

As illustrated in FIG. 5, in the private mode, emission areas may correspond to the second emission areas ER2 defined by the second openings OP2 included in the transmission control layer TCL.

Accordingly, light incident on the transmission control layer TCL may be substantially blocked, and frontal light emission characteristics are substantially realized through the second emission areas ER2 (e.g., rather than through the entirety of the first emission areas ER1), and a viewing angle may be reduced.

FIG. 6 is a schematic cross-sectional view illustrating emission characteristics in a normal mode of a display device in accordance with embodiments.

Referring to FIG. 6, in the on state, where power is applied between the first electrode 150 and the second electrode 170 (e.g., when the display device applies power to the first electrode 150 or the second electrode 170), a vertical electric field may be applied within the transmission conversion layer 160.

Accordingly, an orientation of the liquid crystal material 162 and the dye material 165 may change to a vertical orientation, and the transmission control layer TCL may be converted to a normal mode (e.g., transmissive mode).

In the normal mode, light generated from each pixel may penetrate the transmission control layer TCL. Accordingly, the first emission areas ER1 formed by the first openings OP1 of the pixel-defining layer PDL may be utilized as a whole as emission areas.

Thus, a frontal light emission may be realized from entire areas of the first emission areas ER1. Furthermore, a side light emission may be increased as light may pass through the transmission control layer TCL, and the viewing angle may be increased.

According to the example embodiments described herein, the private mode and the normal mode may selectively be implemented by a single pixel by applying power to the first electrode 150 and the second electrode 170.

Separating the private and normal pixels from each other may result in mutual image interference or image artifacts of the private and normal pixels. Further, degradations of the private and normal pixels may proceed differently, resulting in uneven image characteristics of the private and normal pixels.

According to embodiments of the present disclosure, the display device may switch between the private and normal modes using the transmission control layer TCL and a single pixel. Thus, the non-uniformity of image artifacts or pixel degradation described herein may be avoided. Further, the on/off (normal/private) switching of the transmission control layer TCL may be readily implemented by utilizing a data line or a power line connected to each pixel.

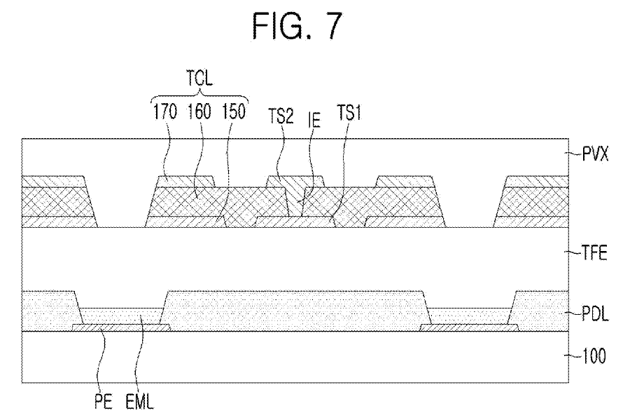

FIG. 7 is a schematic cross-sectional view of a display device in accordance with embodiments. For ease of illustration, in FIG. 7, detailed illustrations of circuit and insulating layers including transistor structures, the hole transport layer HTL, the electron transport layer ETL, the opposing electrode CE, and the like, which are formed on the base substrate 100 illustrated in FIG. 4, are omitted.

A detailed description of substantially the same or similar configurations and structures as those described in FIGS. 3 and 4, which are incorporated by reference, is omitted.

Referring to FIG. 7, the first electrode 150 or the second electrode 170 included in the transmission control layer TCL may be disposed in a same layer or at a same level as the touch-sensing electrode layer.

The touch-sensing electrode layer may include a first touch-sensing electrode layer TS1 and a second touch-sensing electrode layer TS2. The touch-sensing electrode layer may further include an intermediate electrode IE. One of the first touch-sensing electrode layer TS1 and the second touch-sensing electrode layer TS2 may include a sensing electrode layer, and the other may include a bridge electrode. The intermediate electrode IE may include a contact electrode connecting the bridge electrode and the sensing electrode layer to each other.

The first touch-sensing electrode layer TS1 and the second touch-sensing electrode layer TS2 may overlap the pixel-defining layer PDL in the thickness direction and may not overlap the first to third pixels PX1, PX2, and PX3.

The first touch-sensing electrode layer TS1 may be disposed on the encapsulation layer TFE. In some embodiments, the first touch-sensing electrode layer TS1 may be patterned and formed from a same conductive layer as the first electrode 150.

The second touch-sensing electrode layer TS2 may be disposed on a top surface of the transmission conversion layer 160. In some embodiments, the second touch-sensing electrode layer TS2 may be patterned and formed from ae same conductive layer as the second electrode 170.

According to example embodiments, the transmission conversion layer 160 may be provided as an interlayer insulating layer between the first touch-sensing electrode layer TS1 and the second touch-sensing electrode layer TS2.

In some embodiments, a dummy electrode between sensing electrodes included in the touch-sensing electrode layer may be provided as the first electrode 150 or the second electrode 170.

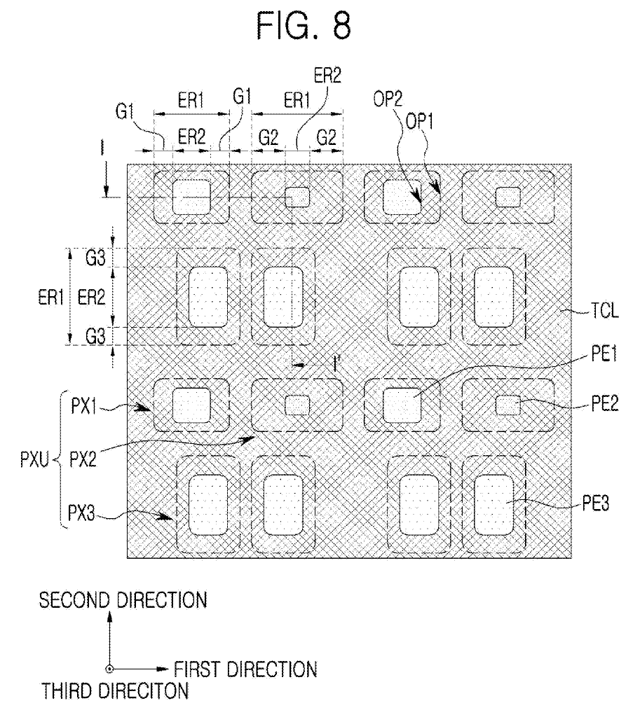

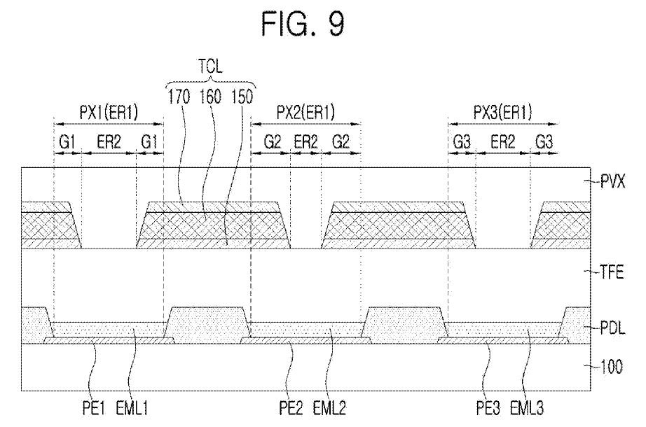

FIG. 8 is a schematic plan view of a display device in accordance with embodiments. FIG. 9 is a schematic cross-sectional view of a display device in accordance with embodiments.

FIG. 8 is a schematic plan view illustrating a pixel arrangement of the display device. FIG. 9 is a schematic cross-sectional view taken along the line I-I' of FIG. 8 in the third direction (or thickness direction).

For ease of illustration, in FIG. 9, detailed illustrations of circuit and insulating layers including transistor structures, the hole transport layer HTL, the electron transport layer ETL, the opposing electrode CE, and the like, which are formed on the base substrate 100 illustrated in FIG. 4, are omitted.

A detailed description of substantially the same or similar configurations and structures as those described in FIGS. 3 and 4, which are incorporated by reference, is omitted.

Referring to FIGS. 8 and 9, at least two of the first pixel PX1, the second pixel PX2, and the third pixel PX3 may have second emission areas ER2 which differ in size compared to one another.

According to example embodiments, the second emission area ER2 of the second pixel PX2 may be smaller than the second emission areas ER2 of the first pixel PX1 and the third pixel PX3.

In the second pixel PX2, an area of a periphery of the first emission area ER1 shielded by the transmission control layer TCL may be increased.

For example, in the first pixel PX1, a separation distance between boundaries of the first emission area ER1 and the second emission area ER2 may be indicated as a first gap G1. In the second pixel PX2, a separation distance between respective boundaries of the first emission area ER1 and the second emission area ER2 may be indicated as a second gap G2. In the third pixel PX3, a separation distance between respective boundaries of the first emission area ER1 and the second emission area ER2 may be indicated as a third gap G3.

The first to third gaps G1, G2, and G3 may refer to maximum horizontal distances between the respective boundaries of the first emission area ER1 and the second emission area ER2 in a corresponding pixel. According to example embodiments, the second gap G2 may be larger than each of the first gap G1 and the third gap G3.

As described herein, according to example embodiments, the first pixel PX1, the second pixel PX2, and the third pixel PX3 may correspond to a red pixel, a green pixel, and a blue pixel, respectively. For example, the green pixel may be a pixel that accounts for the largest proportion of a total emission luminance of the display device.

Accordingly, a size of the second emission area ER2 in the second pixel PX2 corresponding to the green pixel may be reduced to more effectively realize light-blocking characteristics in the private mode.

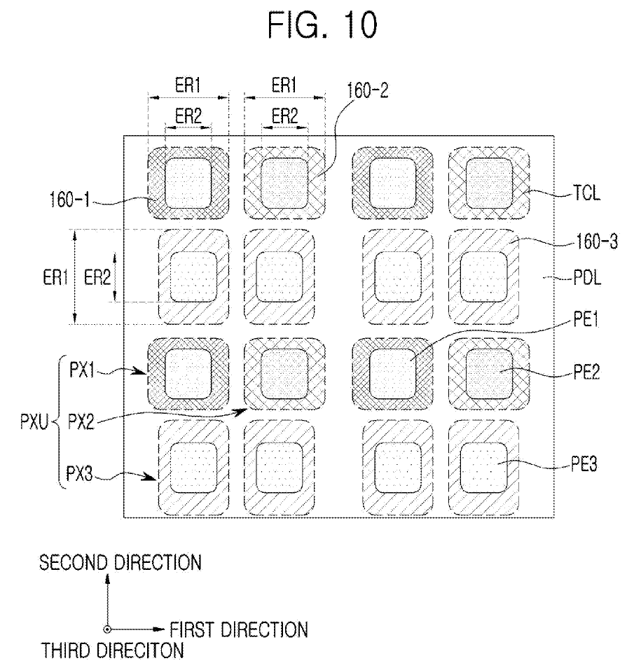

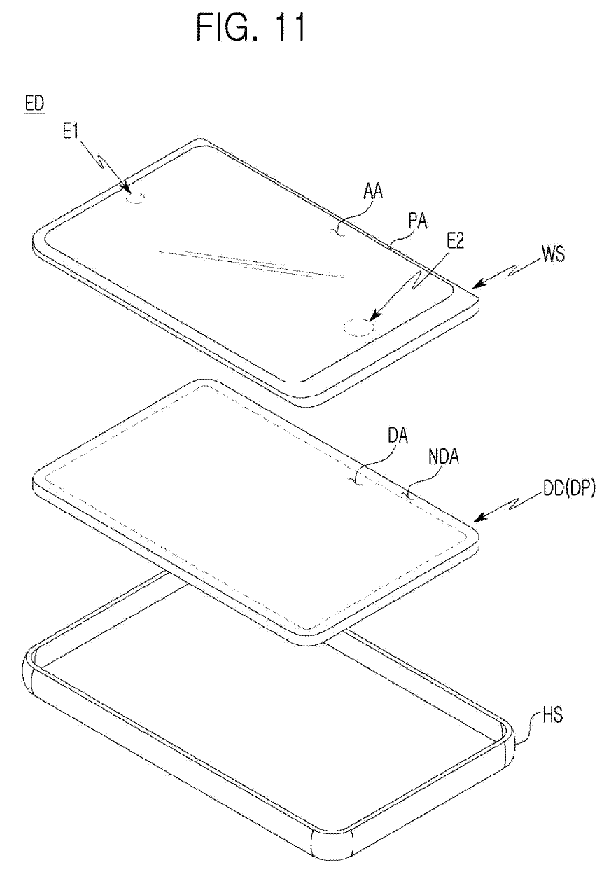

FIG. 10 is a schematic plan view of a display device in accordance with embodiments.

Referring to FIG. 10, the transmission conversion layer 160 of the transmission control layer TCL, which may overlap the first pixel PX1, the second pixel PX2, and the third pixel PX3, may include different colored dyes.

According to example embodiments, the transmission conversion layer 160 may include a first transmission conversion layer 160-1, a second transmission conversion layer 160-2, and a third transmission conversion layer 160-3.

The first transmission conversion layer 160-1 may shield a periphery of the first emission area ER1 of the first pixel PX1 and may include, for example, a dye that may absorb or block red light. The second transmission conversion layer 160-2 may shield a periphery of the first emission area ER1 of the second pixel PX2 and may include, for example, a dye that may absorb or block green light. The third transmission conversion layer 160-3 may shield a periphery of the first emission area ER1 of the third pixel PX3 and may include, for example, a dye that may absorb or block blue light.

By using different dyes based on a color of each pixel, the light-blocking characteristics in the private mode may be more effectively implemented according to the color of the pixel.

As illustrated in FIG. 10, the first transmission conversion layer 160-1, the second transmission conversion layer 160-2, and the third transmission conversion layer 160-3 may be formed in independent patterns to correspond to the first pixel PX1, the second pixel PX2, and the third pixel PX3, respectively.

In some embodiments, the first transmission conversion layer 160-1, the second transmission conversion layer 160-2, and the third transmission conversion layer 160-3 may be in contact with each other and may be provided as substantially one transmission conversion layer 160 as illustrated in FIG. 3.

FIG. 11 is an exploded perspective view of an electronic device in accordance with embodiments.

According to example embodiments, an electronic device ED may be implemented in a form of a mobile phone (or a smartphone), a tablet, a PC, or the like, which may include the display device described herein.

Referring to FIG. 11, the electronic device ED may include a window structure WS, a display device DD, and a housing HS. The display device DD may include a display panel DP including transistors and light-emitting elements as described herein. The housing HS, the display device DD and the window structure WS may be stacked sequentially along the third direction.

The window structure WS may provide an external display surface such as, for example, a viewing surface of the electronic device ED such as the mobile phone, which may be recognized by a user. The window structure WS may include a transparent material film. For example, the window structure WS may include glass (e.g., ultra-thin glass (UTG)), a hard-coated film, a plastic film, or the like.

An outer surface of the window structure WS may include an active area AA and a peripheral area PA. The active area AA may provide a surface on which an image of the display device DD is substantially displayed and on which a user's touch/command is input. The peripheral area PA may correspond substantially to a bezel area of the electronic device ED.

The display device DD or the display panel DP may include the display area DA and the non-display area NDA. The display area DA of the display panel DP may substantially correspond to or overlap the active area AA of the window structure WS. The non-display area NDA of the display panel DP may substantially correspond or overlap the peripheral area PA of the window structure WS. In some embodiments, the peripheral area PA of the window structure WS may further include a margin area that may not overlap the non-display area NDA of the display panel DP.

In some embodiments, the active area AA of the window structure WS may include functional element areas E1, E2 within the active area AA. For example, a first functional element area E1 may be included at one end of the active area AA and may be implemented, for example, in a form of a camera hole. A second functional element area E2 may be provided as a fingerprint-sensing area.

For example, a sensor structure for touch-sensing or fingerprint-sensing may be arranged within the display panel DP, or between the window structure WS and the display panel DP.

The housing HS may be provided as a support frame or a rear housing for the display device DD or the electronic device ED. A cover panel may be disposed between the housing HS and the display panel DP. The housing HS or the cover panel may include a plate (e.g., a SUS plate) supporting the display panel DP. The housing HS or the cover panel may further include an elastic material for shock absorption of the display device DD.

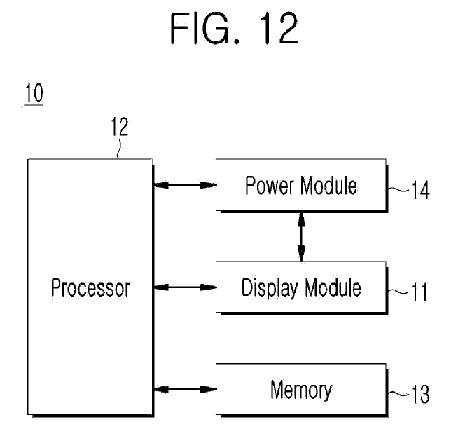

FIG. 12 is a schematic block diagram of an electronic device in accordance with embodiments.

Referring to FIG. 12, the electronic device 10 according to an embodiment may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

The memory 13 may store data information for operation of the processor 12 or the display module 11. In an example in which the processor 12 executes an application stored in the memory 13, image data signals and/or input control signals are delivered to the display module 11, and the display module 11 may process the received signals to output image information through a display screen.

The power module 14 may include a power supply module, such as a power adapter or a battery unit, and a power conversion module that may convert power supplied by the power supply module to generate power for operation of the electronic device 10.

At least one of each of the configurations described herein of the electronic device 10 may be included within the display device according to the embodiments described herein. Furthermore, some of the individual modules that are functionally included within one module may be included within the display device and others may be provided separately from the display device. For example, the display module 11 may include the display device, while the processor 12, memory 13, and power module 14 may be provided in a form of other devices within the electronic device 10 other than the display device.

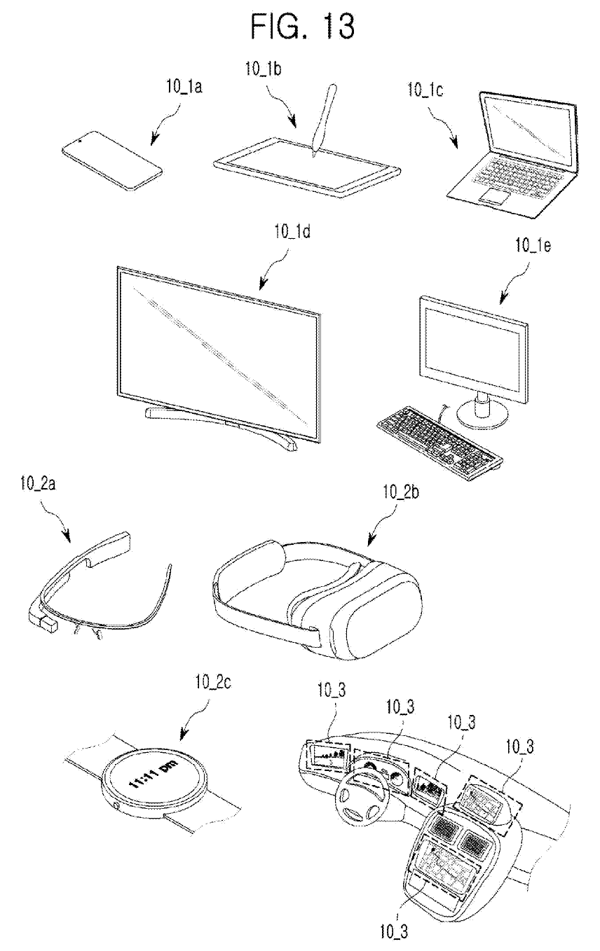

FIG. 13 is schematic diagrams of an electronic device in accordance with embodiments.

Referring to FIG. 13, examples of various electronic devices with display devices according to the embodiments described herein may include electronic devices for displaying images, such as a smartphone 10_1a, a tablet PC 10_1b, a laptop 10_1c, a television 10_1d, a desk monitor 10_1e, and the like, wearable electronic devices including a display module such as smart glass 10_2a, a head-mounted display 10_2b, a smart watch 10_2c, and the like, automotive electronic devices including a display module such as a center information display (CID) disposed at an instrument cluster, a center fascia, and a dashboard of a vehicle, and a room mirror display, and the like. The electronic device may further include a virtual reality glass or an augmented reality glass.

In the display device and the electronic device according to embodiments of the present disclosure, a transmission control layer overlapping an emission area defined by a pixel electrode or a pixel-defining layer and capable of adjusting an area of the emission area according to a normal mode or a private mode may be provided. Since the emission area is adjusted according to the normal mode or the private mode within each pixel, image residuals and image unevenness due to separation of normal and private pixels may be prevented.

What is claimed is:

1. A display device, comprising:
a base substrate;
a pixel electrode on the base substrate;
a pixel-defining layer overlapping the pixel electrode on the base substrate and having a first opening defining a pixel;
a light-emitting layer on the pixel electrode within the first opening; and
a transmission control layer on the pixel-defining layer and the light-emitting layer and having a second opening overlapping the first opening and having an area smaller than the first opening.

2. The display device of claim 1, wherein the transmission control layer comprises a first electrode, a second electrode, and a transmission conversion layer between the first electrode and the second electrode.

3. The display device of claim 2, wherein the transmission conversion layer comprises a liquid crystal material or a dichroic dye material.

4. The display device of claim 2, wherein:
the display device further comprises a touch-sensing electrode layer on the pixel-defining layer, and
the first electrode or the second electrode is positioned at a same level as the touch-sensing electrode layer.

5. The display device of claim 4, wherein:
the touch-sensing electrode layer comprises a first touch-sensing electrode layer and a second touch-sensing electrode layer, and
the transmission conversion layer is provided as an insulating layer between the first touch-sensing electrode layer and the second touch-sensing electrode layer.

6. The display device of claim 2, wherein:
the display device operates according to a private mode in which no power is applied to the first electrode and the second electrode by the display device; and
the display device operates according to a normal mode in which power is applied to the first electrode and the second electrode by the display device.

7. The display device of claim 6, wherein:
a first emission area corresponding to the first opening is driven in the normal mode; and
a second emission area corresponding to the second opening and having a reduced area from the first emission area is driven in the private mode.

8. The display device of claim 7, wherein:
the pixel comprises a first pixel, a second pixel, and a third pixel of different colors, and
an area of the second emission area comprised in the second pixel is smaller than an area of the second emission area comprised in each of the first pixel and the third pixel.

9. The display device of claim 8, wherein the second pixel corresponds to a green pixel.

10. The display device of claim 7, wherein:
the pixel comprises a first pixel, a second pixel, and a third pixel of different colors,
the transmission conversion layer comprises a first transmission conversion layer overlapping the first pixel, a second transmission conversion layer overlapping the second pixel, and a third transmission conversion layer overlapping the third pixel, and
the first transmission conversion layer, the second transmission conversion layer, and the third transmission conversion layer respectively comprise dichroic dye materials of different respective colors.

11. The display device of claim 1, wherein the second opening is comprised in the first opening in a plan view.

12. A display device, comprising:
a base substrate;
a pixel electrode on the base substrate;
a pixel-defining layer overlapping the pixel electrode on the base substrate and defining a first emission area associated with operation of a pixel according to a normal mode,
a light-emitting layer on the pixel electrode and corresponding to the first emission area; and
a transmission control layer on the pixel-defining layer and the light-emitting layer, comprised in the first emission area, and defining a second emission area associated with operation of the pixel according to in a private mode.

13. The display device of claim 12, wherein the transmission control layer comprises:
a first electrode;
a second electrode; and
a transmission conversion layer between the first electrode and the second electrode and comprising a liquid crystal material or a dichroic dye material.

14. The display device of claim 13, wherein the liquid crystal material or the dichroic dye material is vertically oriented in the normal mode.

15. The display device of claim 13, wherein the liquid crystal material or the dichroic dye material is randomly oriented in the private mode.

16. The display device of claim 12, wherein:
the pixel comprises a first pixel, a second pixel, and a third pixel of different respective colors,
the pixel-defining layer defines respective first emission areas associated with operation of the first pixel, the second pixel, and the third pixel according to the normal mode,
the transmission control layer defines respective second emission areas associated with operation of the first pixel, the second pixel, and the third pixel according to the private mode,
a second gap, which is a separation distance between respective boundaries of the first emission area and the second emission area associated with the second pixel, is larger than a first gap, which is a separation distance between respective boundaries of the first emission area and the second emission area associated with the first pixel, and
the second gap is larger than a third gap, which is a separation distance between respective boundaries of the first emission area and the second emission area associated with the third pixel.

17. The display device of claim 16, wherein the second pixel corresponds to a green pixel.

18. The display device of claim 12, wherein:
the pixel-defining layer comprises a first opening corresponding to the first emission area; and
the transmission control layer comprises a second opening corresponding to the second emission area and having a smaller area than the first opening.

19. An electronic device, comprising:
a display device;
a memory; and
a processor configured to execute data comprised in the memory to control operation of the display device,
wherein the display device comprises:
a base substrate;
a pixel electrode on the base substrate;
a pixel-defining layer overlapping the pixel electrode on the base substrate and having a first opening defining a pixel;
a light-emitting layer on the pixel electrode within the first opening; and
a transmission control layer on the pixel-defining layer and the light-emitting layer and having a second opening overlapping the first opening and having an area smaller than the first opening.

20. The electronic device of claim 19, wherein the electronic device comprises virtual reality or augmented reality glasses, a smartphone, a tablet PC, a laptop, a television, a desk monitor, a smart glass, a head-mounted display, a smart watch, or an automotive display.
